(19) United States
(12) Patent Application Publication
(10) Pub. No.: US 2012/0085389 A1
(43) Pub. Date: Apr. 12, 2012

(54) LIGHT CONCENTRATOR ASSEMBLY AND SOLAR CELL APPARATUS HAVING SAME

(75) Inventors: KUO-FENG CHIANG, Chu-Nan (TW); YING-CHIEH LU, Chu-Nan (TW); YU-SHU CHEN, Chu-Nan (TW); CHIEN-TING LU, Chu-Nan (TW); YING-CHING CHEN, Chu-Nan (TW); ZHENG-JAY HUANG, Chu-Nan (TW)

(73) Assignee: FOXSEMICON INTEGRATED TECHNOLOGY, INC., Chu-Nan (TW)

(21) Appl. No.: 13/249,240

(22) Filed: Sep. 30, 2011

(30) Foreign Application Priority Data
Oct. 12, 2010 (TW) 099134650

(51) Int. Cl. H01L 31/052; G02B 17/08

(52) U.S. Cl. 136/246; 359/728

(57) ABSTRACT

A light concentrator assembly includes a Fresnel lens, a plano-concave lens, and a CPC. The CPC is aligned with the Fresnel lens and the plano-concave lens. The Fresnel lens unit is configured for converging parallel light transmitted the Fresnel lens. The plano-concave lens is configured for further concentrating the light from the Fresnel lens before the light converged at a point. The CPC is configured for reflecting and directing the light beams from the plano-concave lens to exit through a light output opening of the CPC. The light concentrator assembly has a large incident acceptance angle.

### BACKGROUND

1. Technical Field

The present disclosure relates to a light concentrator assembly and a related solar cell apparatus.

2. Description of Related Art

Many solar cell apparatuses use reflectors to reflect light to the solar cell, or use convex lenses to converge light onto the solar cell. However, the reflectors and convex lenses do not prove great light concentration uniformity and great light concentration efficiency, and so the solar cell cannot be fully excited to work at its full potential.

What is needed, therefore, is a light concentrator assembly and a solar cell apparatus with same, which can overcome the above shortcomings.

### BRIEF DESCRIPTION OF THE DRAWINGS

Many aspects of the light concentrator assembly and solar cell apparatus can be better understood with reference to the following drawings. The components in the drawings are not necessarily drawn to scale, the emphasis instead being placed upon clearly illustrating the principles of the present light concentrator assembly and solar cell apparatus. Moreover, in the drawings, like reference numerals designate corresponding parts throughout the several views.

FIG. 1 is a schematic, cross-sectional view of a solar cell apparatus in accordance with one embodiment, the solar cell apparatus including a light concentrator assembly and a solar cell device.

FIG. 2 is an output flux distribution diagram of the light concentrator assembly of FIG. 1, under conditions that a distance D between a Fresnel lens surface and a light output opening is about 131 mm, and a light incident angle relative to the light incident surface of the Fresnel lens is 0 degrees.

FIG. 3 is similar to FIG. 2, but with a light incident angle relative to the light incident surface of 1 degrees.

FIG. 4 shows the variations of the concentration efficiency of the light concentrator assembly of FIG. 1 when the light incident angle varies between 0 degrees and 1.6 degrees.

### DETAILED DESCRIPTION

Embodiments of the present light concentrator assembly and solar cell apparatus will now be described in detail below and with reference to the drawings.

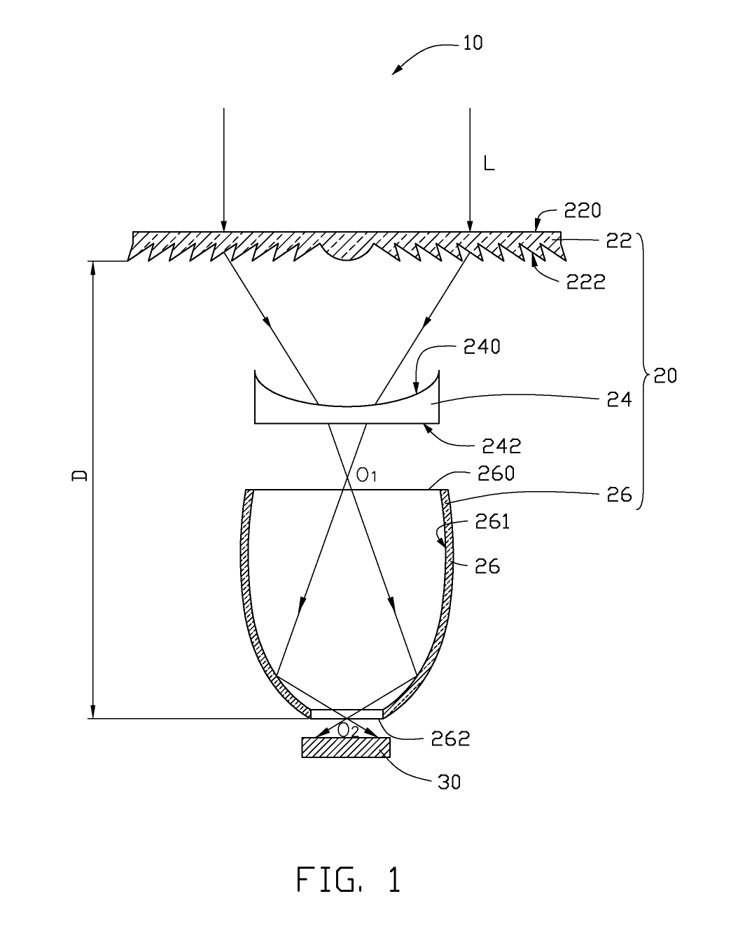

Referring to FIG. 1, a solar cell apparatus 10 includes a light concentrator assembly 20 and a solar cell device 30.

The light concentrator assembly 20 includes a Fresnel lens 22, a plano-concave lens 24, and a compound parabolic concentrator (CPC) 26. The light concentrator assembly 20 is a substantially axial symmetric structure.

The Fresnel lens 22 includes a light incident surface 220 and an opposite Fresnel lens surface 222. The light incident surface 220 is a flat surface, and the first Fresnel lens surface 220 includes a set of concentric annular sections known as “Fresnel zones”. The Fresnel lens surface 222 faces the inside of the light concentrator assembly 10 to help prevent getting dusty. Incident light beams L on the light incident surface 220 is converged after transmitting through the Fresnel lens surface 222.

The plano-concave lens 24 is aligned with the Fresnel lens 22. A distance between the the plano-concave lens 24 and the Fresnel lens 22 is less than a focal length of the Fresnel lens 22. The plano-concave lens 24 has a concave surface 240 facing the Fresnel lens surface 222 and an opposite plane surface 242. The plano-concave lens 24 is positioned in the path of the light from the Fresnel lens 22 to further converge the light beams before the light converged to the Fresnel lens 22's focal point (not shown).

The CPC 26 is aligned with the plano-concave lens 24. The CPC 26 includes a light incident opening 260, an opposite light output opening 262, and a parabolic reflecting surface 261 located between the light incident opening 260 and the light output opening 262. The light incident opening 260 opposes the plane surface 242. The light from the plano-concave lens 24 may first be converged before entering the CPC 26. The light from the plano-concave lens 24 then is reflected and guided to the solar cell device 30 by the parabolic reflecting surfaces 261.

The solar cell device 30 is aligned with the light output opening 262 to receive the light output from the light concentrator assembly 10. The solar cell device 30 may have one or more solar cells to convert the light energy to electrical energy. The solar cells device 30 may be attached to the light output opening 262, or under the light output opening 262. The solar cell device 30 may be the same size as the light output opening 262.

A radius of the Fresnel lens is in a range of 50 mm-65 mm. A focal length of the Fresnel lens is in a range of 100 mm-120 mm. A center thickness of the plano-concave lens is in a range of 1 mm-3 mm. A radius of the plano-concave lens is in a range of 10 mm-20 mm. A radius of the light incident opening of the compound parabolic concentrator is in a range of 2 mm-5 mm. A height of the compound parabolic concentrator is in a range of 5 mm-10 mm. A radius of the solar cell device is in a range of 0.5 mm-2.5 mm. In the present embodiment, the radius of the Fresnel lens is about 60 mm, and the focal length of the Fresnel lens is about 118 mm. The center thickness of the plano-concave lens 24 is about 2 mm, and the radius of the plano-concave lens is about 15 mm. The radius of the light incident opening 260 of the CPC 26 is about 3.63 mm. The height of the CPC 26 is about 9 mm, and the radius of the solar cell device 30 is about 1.3 mm.

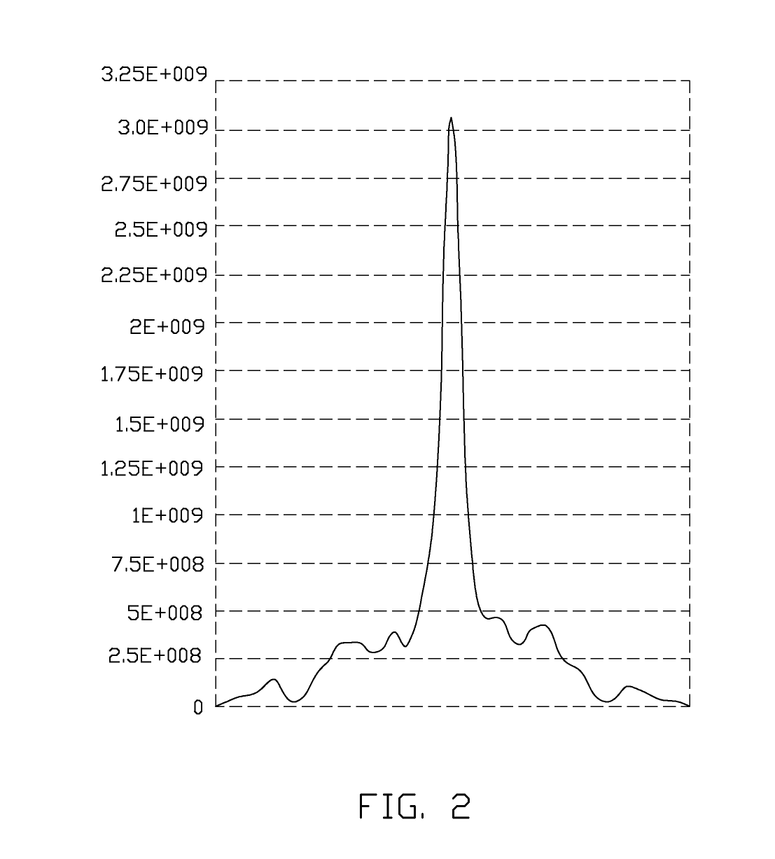

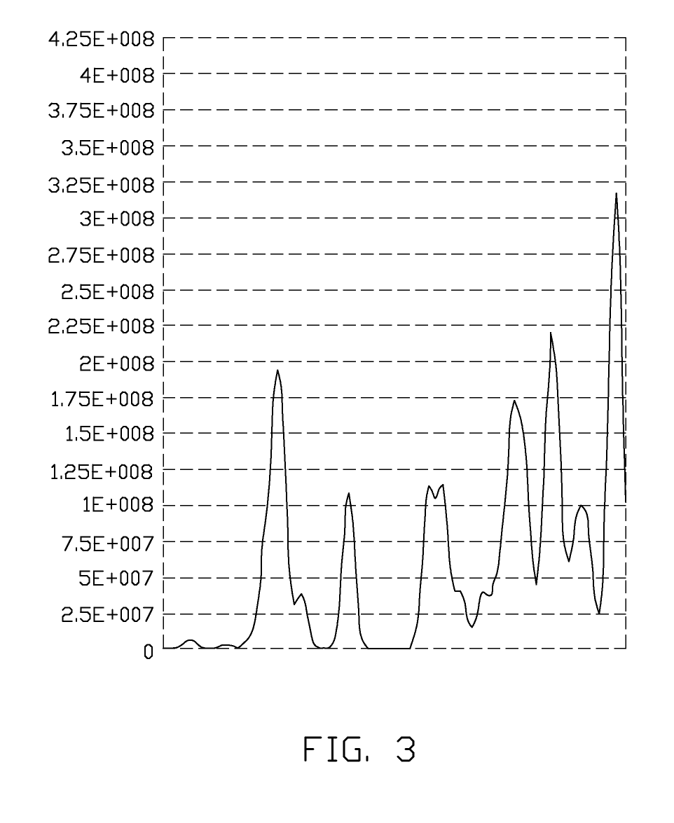

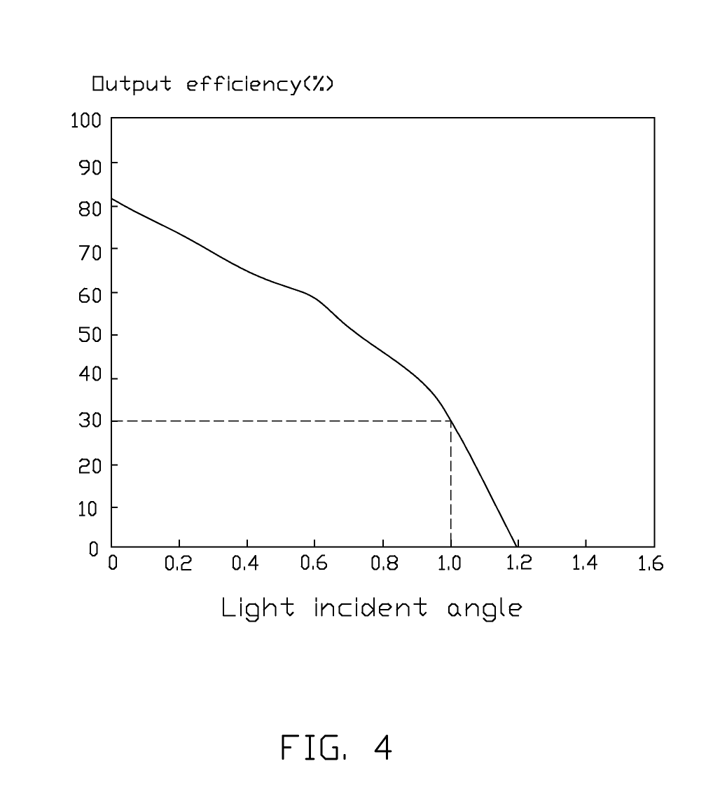

Referring to FIGS. 2 and 4, FIG. 2 is an output flux distribution diagram of the light concentrator assembly 20 of FIG. 1, with a distance D between the Fresnel lens surface and the light output opening being about 131 mm, and a light incident angle being 0 degrees. The distribution is measured in the surface of the solar cell 30. FIG. 3 is similar to FIG. 2, while the incident angle of the incident parallel light relative to the light incident surface 220 is 1 degrees. FIG. 4 shows the variations of the concentration efficiency of the light concentrator assembly 20 of FIG. 1 when the light incident angle varies between 0 degrees and 1.6 degrees.

As seen from FIG. 4, when the light incident angle is 0 degrees, i.e., the light is normally incident to the light concentrator assembly 20, the concentration efficiency (i.e., the ration of output flux to incident flux) of the light concentrator assembly 20 will be greater than 80%. Even if the light incident angle is 1 degrees, the concentration efficiency of the light concentrator assembly 20 can reach a high level, i.e., about 30%, and a good uniformity. Therefore, the light concentrator assembly 20 has a large incident acceptance angle. The solar cell apparatus 10 will also obtain a high photoelectric conversion efficiency.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope of the appended claims.

What is claimed is:

1. A light concentrator assembly, comprising:
a Fresnel lens comprising a light incident surface and an opposite Fresnel lens surface, the Fresnel lens unit configured for converging parallel light transmitting therethrough;
a plano-concave lens aligned with the Fresnel lens, the plano-concave lens having a concave surface facing toward the Fresnel lens and an opposite plane surface; and
a compound parabolic concentrator aligned with the plano-concave lens comprising a light incident opening, an opposite light output opening, and a parabolic surface located between the light incident opening and the light output opening, the plano-concave lens configured for directing the light from Fresnel lens to the compound parabolic concentrator, the compound parabolic concentrator aligned with the Fresnel lens and the plano-concave lens, the parabolic surface configured to reflect and direct the light beams from the plano-concave lens to exit through the light output opening.

2. The light concentrator assembly of claim 1, wherein a distance between the plano-concave lens and the Fresnel lens is less than a focal length of the Fresnel lens.

3. The light concentrator assembly of claim 1, wherein a radius of the Fresnel lens is in a range of 50 mm-65 mm, a focal length of the Fresnel lens is in a range of 100 mm-120 mm, a center thickness of the plano-concave lens is in a range of 1 mm-3 mm, and a radius of the plano-concave lens is in a range of 10 mm-20 mm, a radius of the light incident opening of the compound parabolic concentrator is in a range of 2 mm-5 mm, and a height of the compound parabolic concentrator is in a range of 5 mm-10 mm.

4. The light concentrator assembly of claim 3, wherein the distance between the Fresnel lens surface and the light output opening is 131 mm, when the light incident angle at the light incident surface is 0 degrees, the concentration efficiency of the light concentrator assembly is greater than 80%.

5. The light concentrator assembly of claim 3, wherein the distance between the Fresnel lens surface and the light output opening is 131 mm, when the light incident angle at the light incident surface is 1 degrees, the concentration efficiency of the light concentrator assembly is 30%.

6. A solar cell apparatus comprising:
a light concentrator assembly, comprising:
a Fresnel lens comprising a light incident surface and an opposite Fresnel lens surface, the Fresnel lens unit configured for converging light transmitting therethrough;
a plano-concave lens aligned with the Fresnel lens having a concave surface facing toward the Fresnel lens and an opposite plane surface; and
a compound parabolic concentrator aligned with plano-concave lens comprising a light incident opening, an opposite light output opening, and a parabolic surface located between the light incident opening and the light output opening, the compound parabolic concentrator aligned with the Fresnel lens and the plano-concave lens, the parabolic surface configured to reflect and direct the light beams from the plano-concave lens to exit through the light output opening; and
a solar cell device facing the light output opening and configured for receiving and converting the light from the light output opening into electrical energy.

7. The solar cell apparatus of claim 6, wherein a distance between the plano-concave lens and the Fresnel lens is less than a focal length of the Fresnel lens.

8. The solar cell apparatus of claim 6, wherein the solar cells device is attached to the light output opening.

9. The solar cell apparatus of claim 6, wherein a radius of the Fresnel lens is in a range of 50 mm-65 mm, a focal length of the Fresnel lens is in a range of 100 mm-120 mm, a center thickness of the plano-concave lens is in a range of 1 mm-3 mm, and a radius of the plano-concave lens is in a range of 10 mm-20 mm, a radius of the light incident opening of the compound parabolic concentrator is in a range of 2 mm-5 mm, a height of the compound parabolic concentrator is in a range of 5 mm-10 mm, and a radius of the solar cell device is in a range of 0.5 mm-2.5 mm.

10. The solar cell apparatus of claim 9, wherein the distance between the Fresnel lens surface and the light output opening is 131 mm, when the incident angle of the light at the light incident surface is 0 degrees, the concentration efficiency of the light concentrator assembly is greater than 80%.

11. The solar cell apparatus of claim 9, wherein the distance between the Fresnel lens surface and the light output opening is 131 mm, when the light incident angle at the light incident surface is 1 degrees, the concentration efficiency of the light concentrator assembly is 30%.
